(19) United States
(12) Patent Application Publication
(10) Pub. No.: US 2025/0167004 A1
(43) Pub. Date: May 22, 2025

(54) SEMICONDUCTOR DEVICE INCLUDING METAL GATE STRUCTURE WITH SPECIFIED PROFILE AND METHOD FOR MANUFACTURING THE SAME

(71) Applicant: TAIWAN SEMICONDUCTOR MANUFACTURING COMPANY, LTD., Hsinchu (TW)

(72) Inventors: Chan-Yu TSENG, Hsinchu (TW); Cheng-Chieh HUANG, Hsinchu (TW); Sung-Hsin YANG, Hsinchu (TW); Yao-Jui KUO, Hsinchu (TW); Ying-Ming WANG, Hsinchu (TW); Shih-Hao CHEN, Hsinchu (TW); Ling-Sung WANG, Hsinchu (TW)

(73) Assignee: TAIWAN SEMICONDUCTOR MANUFACTURING COMPANY, LTD., Hsinchu (TW)

(21) Appl. No.: 18/510,794

(22) Filed: Nov. 16, 2023

(51) Int. Cl. H01L 21/3213; H01L 29/423; H01L 29/66; H01L 29/78

(52) U.S. Cl. CPC H01L 21/32135; H10D 30/62; H10D 64/017; H10D 64/518

(57) ABSTRACT

A method for manufacturing a semiconductor device includes: forming a dummy gate structure on a semiconductor substrate, the dummy gate structure including a lower portion disposed on the semiconductor substrate and an upper portion disposed on the lower portion and opposite to the semiconductor substrate; and trimming the lower portion of the dummy gate structure by an etching process such that the lower portion of the dummy gate structure has a width less than that of the upper portion of the dummy gate structure.

### BACKGROUND

The integration density of various electronic components, such as transistors, diodes, resistors, capacitors, etc., is being continuously improved in integrated circuit industry by continual reduction in minimum feature sizes. As the feature sizes are reduced, a process window for forming source/drain structures adjacent to metal gate structures is reduced, which may cause a bridging problem between the metal gate structures and the adjacent source/drain structures of the electronic components (for example, but not limited to, the transistors).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device including a metal gate structure with a specified profile in accordance with some embodiments.

FIGS. 2 to 13 illustrate schematic views of some intermediate stages of the method depicted in FIGS. 1A and 1B in accordance with some embodiments.

FIG. 14 is a graph showing a relationship between Weibull probability and time-to-breakdown of the semiconductor device measured by a Core SVT-PMOS TDDB (standard voltage threshold PMOS time dependent dielectric breakdown) test at a high voltage ranging from about 3.0 V to about 3.2 V in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “downward,” “upwardly,” “upper,” “lower,” “over,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

With development of semiconductor technology, semiconductor integrated circuit (IC) chips have been applied in various fields. In recent years, application need for the semiconductor IC chips is gradually increased. In order to meet application needs, an increased device functional density (i.e., the number of electrical devices per chip area) in a semiconductor IC chip is desired. In this case, a reduction in size of each electrical device (for example, but not limited to, a transistor, a diode, an inverter, or other electrical devices) is required, so that more and more electrical devices can be included in the semiconductor IC chip. However, as the size of each electrical device in the semiconductor IC chip is becoming smaller, there may exist some electrical issues or limitations on the device performance of each electrical device. For example, a distance between a gate feature (e.g., a metal gate (MG) structure) and a conductive feature (e.g., a metal deposition (MD), i.e., a metal contact) or a source/drain structure adjacent to the gate feature may be shortened, resulting in a bridging issue (e.g., formation of an open circuit) therebetween.

The present disclosure is directed to a method for manufacturing a semiconductor device in which a metal gate structure with a specified profile is formed, so as to increase a process window for forming a source/drain structure adjacent to the metal gate structure and to eliminate an issue of an open circuit being formed between the metal gate structure and the metal contact connected to the source/drain structure.

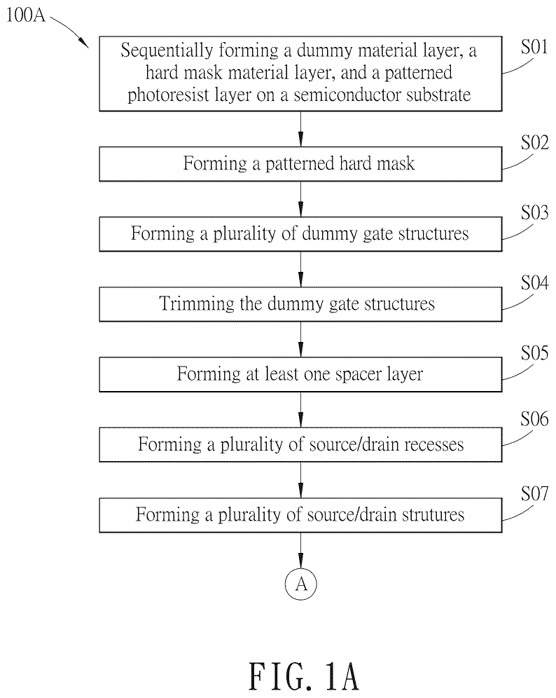

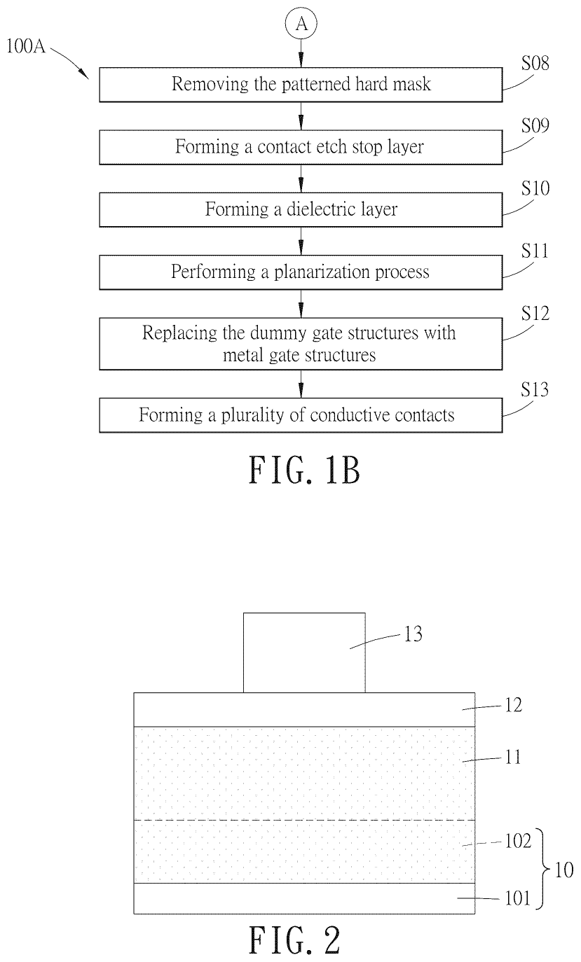

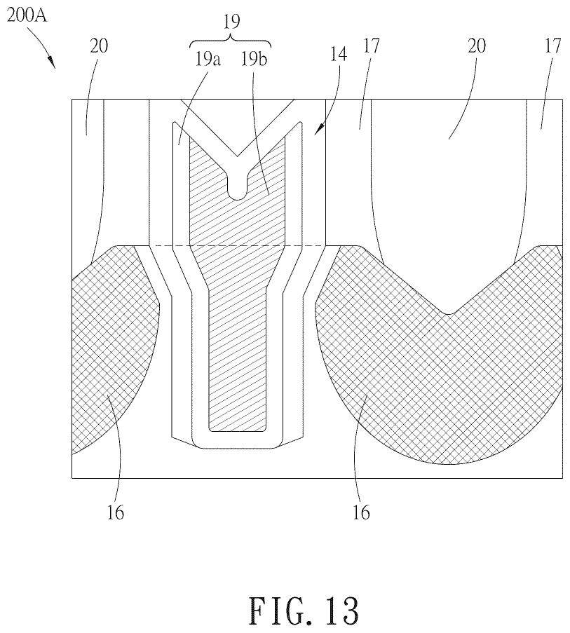

FIGS. 1A and 1B are flow diagrams illustrating a method 100A for manufacturing a semiconductor device (for example, a semiconductor device 200A shown in FIG. 13) in accordance with some embodiments. FIGS. 2 to 12 illustrate schematic views of some intermediate stages of the method 100A in accordance with some embodiments. Some portions may be omitted in FIGS. 2 to 13 for the sake of brevity. Additional steps can be provided before, after or during the method 100A, and some of the steps described herein may be replaced by other steps or be eliminated. Similarly, further additional features may be present in the semiconductor device 200A, and/or features present may be replaced or eliminated in additional embodiments.

Referring to FIG. 1A and the example illustrated in FIG. 2, the method 100A begins at step S01, where a dummy material layer 11, a hard mask material layer 12, and a patterned photoresist layer 13 are formed sequentially on a semiconductor substrate 10.

The semiconductor substrate 10 may include, for example, but not limited to, an elemental semiconductor or a compound semiconductor. In some embodiments, the elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 10 may include a multilayer compound semiconductor structure. In some embodiments, the semiconductor substrate 10 may be a semiconductor on insulator (SOI) (e.g., silicon germanium on insulator (SGOI)). Generally, an SOI substrate includes a layer of a semiconductor material, such as epitaxial silicon (Si), germanium (Ge), silicon germanium (SiGe), or combinations thereof. The SOI substrate may be doped with a P-type dopant, for example, but not limited to, boron (Br), aluminum (Al), or gallium (Ga). Other suitable P-type dopant materials are within the contemplated scope of the present disclosure. Alternatively, the SOI substrate may be doped with an N-type dopant, for example, but not limited to, nitrogen (N), phosphorus (P), or arsenic (As). Other suitable N-type dopant materials are within the contemplated scope of the present disclosure. In some embodiments, the semiconductor substrate 10 may include a main portion 101, and a plurality of fin portions 102 that are disposed on the main portion 101 and that are spaced apart from one another (not shown). One of the fin portions 102 is shown in FIG. 2.

The dummy material layer 11 is formed on the semiconductor substrate 10 and across the fin portions 102 of the semiconductor substrate 10. In some embodiments, the dummy material layer 11 includes polysilicon. In some embodiments, the dummy material layer 11 may be formed on the semiconductor substrate 10 by a suitable process as known to those skilled in the art of semiconductor fabrication, for example, but not limited to, chemical vapor deposition (CVD), atomic layer deposition (ALD), high density plasma CVD (HDPCVD), remote plasma CVD (RPCVD), plasma enhanced CVD (PECVD), or plasma enhanced ALD (PEALD). Other suitable processes are within the contemplated scope of the present disclosure. In some embodiments, a gate dielectric material layer (not shown) may be formed on the semiconductor substrate 10 before the dummy material layer 11 is formed. In some embodiments, the gate dielectric material layer may be formed by a suitable process as known to those skilled in the art of semiconductor fabrication, for example, but not limited to, CVD, ALD, HDPCVD, RPCVD, PECVD, or PEALD. Other suitable processes are within the contemplated scope of the present disclosure. In some embodiments, the gate dielectric material layer may include, for example, but not limited to, silicon oxide, silicon oxynitride, silicon nitride, carbon doped silicon oxide, a high-k dielectric material (for example, but not limited to, HfO₂, HfSiO, HfSiON, HfTaO, HfTiO, HfZrO, other suitable high-k dielectric materials), or combinations thereof. Other suitable dielectric materials are within the contemplated scope of the present disclosure.

The hard mask material layer 12 is formed on the dummy material layer 11. In some embodiments, the hard mask material layer 12 may include a nitride-based film (for example, but not limited to, a silicon nitride film) disposed on the dummy material layer 11, and an oxide-based film (for example, but not limited to, a silicon oxide film) disposed on the nitride-based film. In some embodiments, each of the nitride-based film and the oxide-based film may be formed independently by a suitable process as known to those skilled in the art of semiconductor fabrication, for example, but not limited to, CVD, ALD, PECVD, or PEALD. Other suitable processes are within the contemplated scope of the present disclosure.

The patterned photoresist layer 13 is formed on the hard mask material layer 12. In some embodiments, the patterned photoresist layer 13 may include a lower patterned photoresist film (not shown) disposed on the hard mask material layer 12, a middle patterned photoresist film (not shown) disposed on the lower patterned photoresist film, and an upper patterned photoresist film disposed on the middle patterned photoresist film. In some embodiments, the patterned photoresist layer 13 may be formed by forming a lower photoresist film, a middle photoresist film, and an upper photoresist film sequentially on the hard mask material layer 12, and then patterning the upper photoresist film, the middle photoresist film, and the lower photoresist film sequentially. In some embodiments, the upper photoresist film is patterned by a photolithography technique, which may include soft-baking, exposing through a photomask (not shown), post-exposure baking, developing, and hard-baking, to form the upper patterned photoresist film. The middle photoresist film and the lower photoresist film are patterned sequentially by one or more etching processes (for example, but not limited to, a dry etching process, a wet etching process, or a combination thereof) through the upper patterned photoresist film to form the middle patterned photoresist film and the lower patterned photoresist film, so as to obtain the patterned photoresist layer 13.

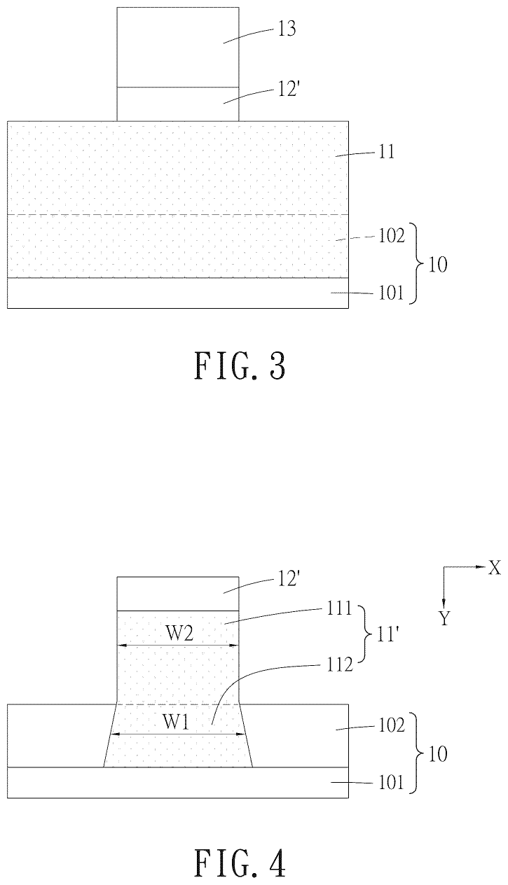

Referring to FIG. 1A and the example illustrated in FIG. 3, the method 100A then proceeds to step S02, where a patterned hard mask 12′ is formed. In some embodiments, the patterned hard mask 12′ may be formed by patterning the hard mask material layer 12 of the structure shown in FIG. 2 by one or more suitable etching processes (for example, but not limited to, a dry etching process, a wet etching process, or a combination thereof) through the patterned photoresist layer 13. In some embodiments, sidewalls of the patterned hard mask 12′ may be further trimmed by a suitable trimming process (for example, but not limited to, a dry etching process). After the patterned hard mask 12′ is formed, the patterned photoresist layer 13 is removed from the patterned hard mask 12′ by a suitable removing process (for example, but not limited to, an ashing process).

Referring to FIG. 1A and the example illustrated in FIG. 4, the method 100A then proceeds to step S03, where a plurality of dummy gate structures 11′ are formed across the fin portions 102 of the semiconductor substrate 10. One of the dummy gate structures 11′ is shown in FIG. 4. In some embodiments, the dummy gate structures 11′ may be formed by the sub-steps of (i) a main etch process, (ii) a first soft-landing etch process, and (iii) a second soft-landing etch process. In some embodiments, each of the main etch process, the first soft-landing etch process, and the second soft-landing etch process is a dry etching process. In some embodiments, an upper portion 111 of each of the dummy gate structures 11′ is formed after the dummy material layer 11 of the structure shown in FIG. 3 is patterned by the main etch process through the patterned hard mask 12′. A lower portion 112 of each of the dummy gate structures 11′ is formed after the dummy material layer 11 shown in FIG. 3 is further patterned by the first soft-landing etch process and the second soft-landing etch process through the patterned hard mask 12′. The dummy gate structures 11′ are formed accordingly. The lower portion 112 of each of the dummy gate structures 11′ has a first width (W1) in a horizontal direction (X) parallel to an extension direction of the fin portions 102 of the semiconductor substrate 10, the upper portion 111 of each of the dummy gate structures 11′ has a second width (W2) in the horizontal direction (X), and the first width (W1) is greater than the second width (W2). In some embodiments, the first width (W1) of the lower portion 112 of each of the dummy gate structures 11′ increases gradually in a downward direction (Y) (i.e., a direction transverse to the horizontal direction (X) and directed toward a bottom end of the lower portion 112 of each of the dummy gate structures 11′).

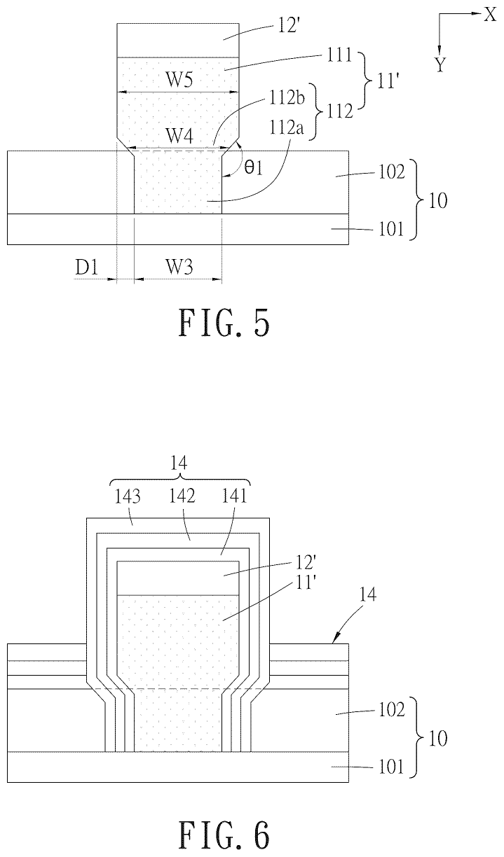

Referring to FIG. 1A and the example illustrated in FIG. 5, the method 100A then proceeds to step S04, where the dummy gate structures 11′ of the structure shown in FIG. 4 are trimmed. In some embodiments, the dummy gate structures 11′ of the structure shown in FIG. 4 may be trimmed by the sub-steps of (a) a first over-etching, (b) a second over-etching, (c) a third over-etching, (d) a first corner-trimming, and (e) a second corner-trimming. In some embodiments, each of the first over-etching, the second over-etching, the third over-etching, the first corner-trimming, and the second corner-trimming is performed by a dry etching process. In some embodiments, the first over-etching is a dry etching process with a first pulsed bias voltage, a first bias power, and a first etching gas mixture including a first etching gas, a second etching gas, and a third etching gas. In some embodiments, the first etching gas is chlorine gas, the second etching gas is hydrogen bromide gas, and the third etching gas is oxygen gas. In some embodiments, the second over-etching is performed after the first over-etching, and is a dry etching process with a second pulsed bias voltage, a second bias power, and a second etching gas mixture including a first etching gas, a second etching gas, and a third etching gas. In some embodiments, the first etching gas is chlorine gas, the second etching gas is hydrogen bromide gas, and the third etching gas is oxygen gas. The chlorine gas included in the second etching gas mixture for the second over-etching has a concentration greater than that of chlorine gas included in the first etching gas mixture for the first over-etching. The first pulsed bias voltage for the first over-etching may be the same as or different from the second pulsed bias voltage for the second over-etching. In some embodiments, the third over-etching is performed after the second over-etching, and is a dry etching process with a first continuous bias voltage, a third bias power, and a third etching gas mixture including a first etching gas, a second etching gas, and a third etching gas. In some embodiments, the first etching gas is chlorine gas, the second etching gas is hydrogen bromide gas, and the third etching gas is oxygen gas. The chlorine gas included in the third etching gas mixture for the third over-etching has a concentration less than that of chlorine gas included in the second etching gas mixture for the second over-etching. In some embodiments, the first corner-trimming is performed after the third over-etching, and is a dry etching process with a second continuous bias voltage, a fourth bias power, and a fourth etching gas mixture including a first etching gas, a second etching gas, and a third etching gas. In some embodiments, the first etching gas is chlorine gas, the second etching gas is hydrogen bromide gas, and the third etching gas is oxygen gas. In some embodiments, the second corner-trimming is performed after the first corner-trimming, and is a dry etching process with a third continuous bias voltage, a fifth bias power, and a fifth etching gas mixture including a first etching gas, a second etching gas, and a third etching gas. In some embodiments, the first etching gas is chlorine gas, the second etching gas is hydrogen bromide gas, and the third etching gas is oxygen gas. The fifth bias power for the second corner-trimming is greater than the first bias power for the first over-etching, the second bias power for the second over-etching, the third bias power for the third over-etching, and the fourth bias power for the first corner-trimming. The chlorine gas included in the fifth etching gas mixture for the second corner-trimming has a concentration greater than that of chlorine gas included in the fourth etching gas mixture for the first corner-trimming. The first continuous bias voltage for the third over-etching, the second continuous bias voltage for the first corner-trimming, and the third continuous bias voltage for the second corner-trimming may be the same as or different from each other.

Each of the dummy gate structures 11′, after being trimmed by the first over-etching, the second over-etching, the third over-etching, the first corner-trimming, and the second corner-trimming, has a profile shown in FIG. 5, in which the lower portion 112 of each of the dummy gate structures 11′ has a width in the horizontal direction (X), which is less than a width of the upper portion 111 of each of the dummy gate structures 11′ in the horizontal direction (X). The lower portion 112 of each of the dummy gate structures 11′, after being trimmed, includes a lower part 112a and an upper part 112b connected between the lower part 112a and the upper portion 111. The lower part 112a of the lower portion 112 of each of the dummy gate structures 11′ has a width (W3) in the horizontal direction (X). The upper portion 111 of each of the dummy gate structures 11′ has a width (W5) in the horizontal direction (X), which is greater than the width (W3) of the lower part 112a of the lower portion 112 of each of the dummy gate structures 11′. The upper part 112b of the lower portion 112 of each of the dummy gate structures 11′ is tapered in the downward direction (Y) from the upper portion 111 of each of the dummy gate structures 11′ to the lower part 112a of the lower portion 112 of each of the dummy gate structures 11′. The upper part 112b of the lower portion 112 of each of the dummy gate structures 11′ has a width (W4) in the horizontal direction (X), which ranges from about the width (W3) to about the width (W5). In some embodiments, the width (W5) ranges from about 25 nm to about 6000 nm. In some embodiments, a distance (D1) between a sidewall of the upper portion 111 of each of the dummy gate structures 11′ and a corresponding sidewall of the lower part 112a of the lower portion 112 of the each of the dummy gate structures 11′ in the horizontal direction (X) ranges from about 5 nm to about 10 nm. If the distance (D1) is less than 5 nm, an issue of forming an open circuit (or bridging) between metal gate structures 19 and source/drain structures 16 (see FIG. 12) may occur. If the distance (D1) is greater than 10 nm, voids formed by removing the dummy gate structures 11′ may be too small to form the metal gate structures 19. A sidewall of the upper part 112b of the lower portion 112 of the each of the dummy gate structures 11′ and a corresponding sidewall of the lower part 112a of the lower portion 112 of the each of the dummy gate structures 11′ define an angle (Θ1) which is greater than about 90° and less than about 150°. If the angle is greater than 150°, an issue of formation of the open circuit (or bridging) between the metal gate structures 19 and the source/drain structures 16 may occur.

Referring to FIG. 1A and the example illustrated in FIG. 6, the method 100A then proceeds to step S05, where at least one spacer layer is formed. A first spacer layer 14 is conformally formed on the structure shown in FIG. 5 to cover the patterned hard mask 12′, the dummy gate structures 11′, and the semiconductor substrate 10. In some embodiments, the first spacer layer 14 includes a first spacer film 141 conformally formed on the structure shown in FIG. 5, a second spacer film 142 conformally formed on the first spacer film 141, and a third spacer film 143 conformally formed on the second spacer film 142. Each of the first spacer film 141, the second spacer film 142, and the third spacer film 143 may be conformally formed by a suitable deposition process as known to those skilled in the art of semiconductor fabrication, for example, but not limited to, CVD, PECVD, ALD, or PEALD. Other suitable processes are within the contemplated scope of the present disclosure. In some embodiments, each of the first spacer film 141, the second spacer film 142, and the third spacer film 143 may include, for example, but not limited to, a low-k dielectric material. In some embodiments, examples of the low-k dielectric material may include, for example, but not limited to, silicon oxide, silicon nitride, silicon carbide, silicon oxycarbide, silicon oxynitride, silicon carbonitride, silicon oxycarbonitride, plasma-enhanced oxide (PEOX), and combinations thereof. Other suitable dielectric materials are within the contemplated scope of the present disclosure. The first spacer film 141, the second spacer film 142, and the third spacer film 143 may be the same as or different from each other.

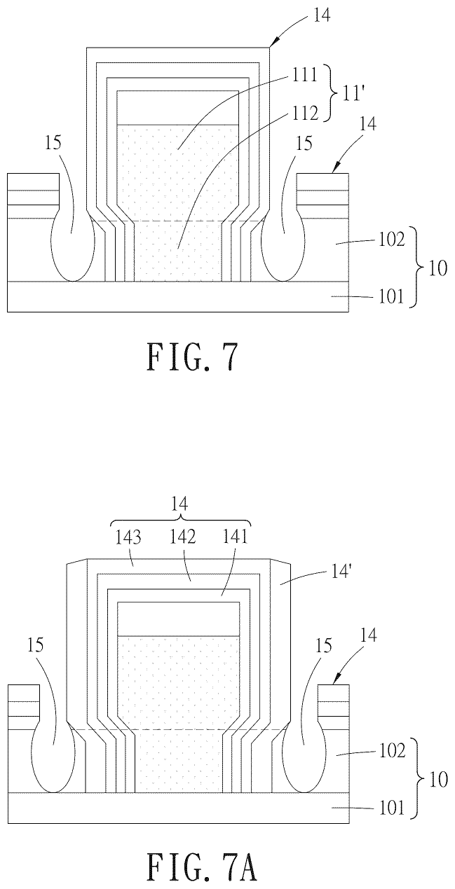

Referring to FIG. 1A and the example illustrated in FIG. 7, the method 100A then proceeds to step S06, where a plurality of source/drain recesses 15 are formed. Each pair of the source/drain recesses 15 are formed at two opposite sides of a corresponding one of the dummy gate structures 11′. In some embodiments, the source/drain recesses 15 may be formed by recessing the semiconductor substrate 10 using an anisotropic etching process. In some embodiments, the anisotropic etching process may be an anisotropic dry etching process. Other suitable anisotropic etching processes as known to those skilled in the art of semiconductor fabrication are within the contemplated scope of the present disclosure. As described above, the width of the lower portion 112 of each of the dummy gate structures 11′ is less than the width of the upper portion 111 of each of the dummy gate structures 11′. A process window for forming the source/drain recesses 15 adjacent to the dummy gate structures 11′ can be increased, and an issue of damage to the first spacer layer 14 and the dummy gate structures 11′ which may be caused by the anisotropic etching process for forming the source/drain recesses 15 can be prevented, such that an issue of forming an open circuit (or bridging) between metal gate structures 19 and source/drain structures 16 (see FIG. 12) can be eliminated.

Referring to the example illustrated in FIG. 7A, in some embodiments, a second spacer layer 14′ may be conformally formed on sidewalls of the first spacer layer 14 before the source/drain recesses 15 are formed. In some embodiments, the second spacer layer 14′ may be formed by conformally depositing a spacer material layer on the first spacer layer 14 and then anisotropically etching the spacer material layer by, for example, but not limited to, an anisotropic dry etching process, to etch away horizontal portions of the spacer material layer, thereby forming the second spacer layer 14′ which extends upwardly from the semiconductor substrate 10 to cover the sidewalls of the first spacer layer 14. The conformal deposition and the material for forming the second spacer layer 14′ may be the same as or similar to the conformal deposition and the material for forming the first spacer layer 14′ as described above with reference to FIG. 6, and thus, details thereof are omitted for the sake of brevity.

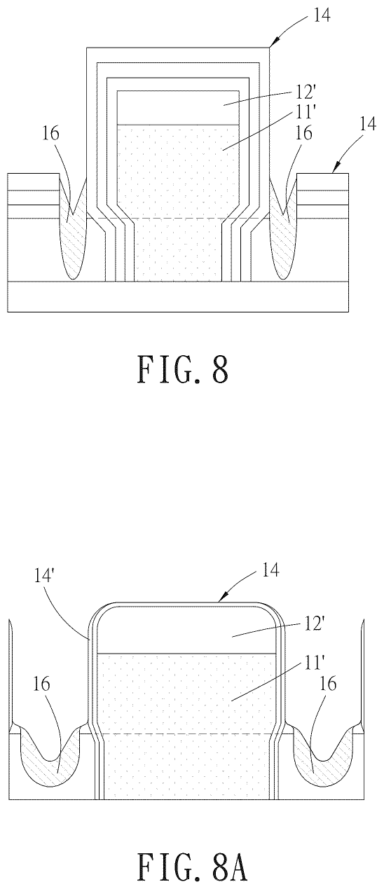

Referring to FIG. 1A and the example illustrated in FIGS. 8 and 8A, the method 100A then proceeds to step S07, where a plurality of source/drain structures 16 are formed. A pair of the source/drain structures 16 are disposed at two opposite sides of a corresponding one of the dummy gate structures 11′. The source/drain structures 16 are respectively formed in the source/drain recesses 15 of the structure shown in FIG. 7 or FIG. 7A. In some embodiments, the source/drain structures 16 may be formed by epitaxially growing a semiconductor material in the source/drain recesses 15 of the structure shown in FIG. 7 or FIG. 7A through a selective epitaxial growth (SEG) process. In some embodiments, the source/drain structures 16 may be, for example, but not limited to, crystalline silicon (or other suitable semiconductor materials) in-situ doped with a P-type dopant during the SEG process, so as to form PMOS transistors (P-type metal oxide semiconductor field effect transistors). The P-type dopant may be, for example, but not limited to, boron, aluminum, gallium, indium, BF₂, or combinations thereof. Other suitable materials are within the contemplated scope of the present disclosure. In some embodiments, the source/drain structures 16 may include one or multiple layers of the semiconductor material. In some embodiments, the source/drain structures 16 may be fabricated by forming a SiGe alloy layer in the source/drain recesses 15 of the structure shown in FIG. 7 or FIG. 7A through the SEG process and forming a Si cap layer on top of the SiGe alloy layer, followed by implanting a P-type light doping grain (for example but not limited to, boron, aluminum, gallium, indium, BF₂, other suitable materials, or combinations thereof). In some embodiments, the source/drain structures 16 may be, for example, but not limited to, crystalline silicon (or other suitable semiconductor materials) in-situ doped with an N-type dopant during the SEG process, so as to form NMOS transistors (N-type metal oxide semiconductor field effect transistors). The N-type dopant may be, for example, but not limited to, phosphorous, nitrogen, arsenic, antimony, or combinations thereof. Other suitable materials are within the contemplated scope of the present disclosure. In some embodiments, the source/drain structures 16 may be fabricated by forming a SiGe alloy layer in the source/drain recesses 15 of the structure shown in FIG. 7 or FIG. 7A through the SEG process and forming a Si cap layer on top of the SiGe alloy layer, followed by implanting an N-type light doping drain (for example but not limited to, phosphorous, nitrogen, arsenic, antimony, other suitable materials, or combinations thereof).

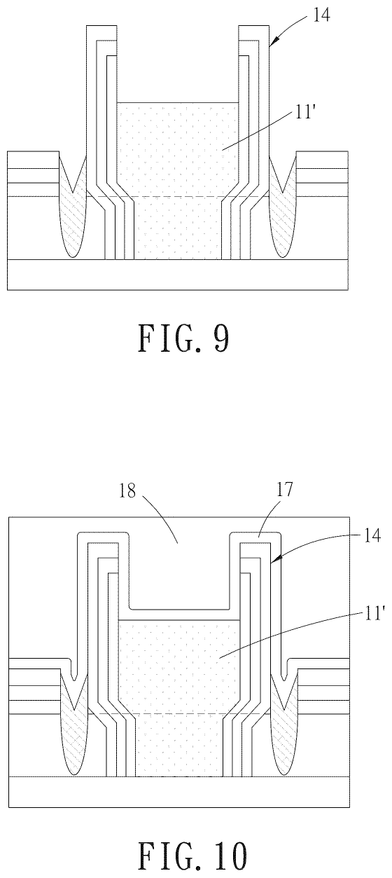

Referring to FIG. 1B and the example illustrated in FIG. 9, the method 100A then proceeds to step S08, where the patterned hard mask 12′ of the structure shown in FIG. 8 is removed. In some embodiments, the patterned hard mask 12′ may be removed using an anisotropic etching process through a patterned mask (not shown) disposed on the structure shown in FIG. 8. In some embodiments, the anisotropic etching process may be an anisotropic dry etching process. Other suitable anisotropic etching processes as known to those skilled in the art of semiconductor fabrication are within the contemplated scope of the present disclosure. The anisotropic etching process is performed to remove portions of the first spacer layer 14 disposed on the patterned hard mask 12′ and the patterned hard mask 12′ (see FIG. 8) so as to expose the dummy gate structures 11′. Thereafter, the patterned mask is removed by a suitable removal process (for example, but not limited to, an etching process or an ashing process) as known to those skilled in the art of semiconductor fabrication.

Referring to FIG. 1B and the example illustrated in FIG. 10, the method 100A then proceeds to step S09, where a contact etch stop layer 17 is formed. The contact etch stop layer (CESL) 17 is conformally formed on the structure shown in FIG. 9. In some embodiments, CESL 17 may include, for example, but not limited to, silicon nitride, carbon-doped silicon nitride, or a combination thereof. Other suitable materials are within the contemplated scope of the present disclosure. In some embodiments, the CESL 17 may be formed by a suitable deposition process as known to those skilled in the art of semiconductor fabrication, for example but not limited to, CVD, PECVD, ALD, or PEALD. Other suitable processes are within the contemplated scope of the present disclosure.

Referring to FIG. 1B and the example illustrated in FIG. 10, the method 100A then proceeds to step S10, where a dielectric layer 18 is formed on the CESL 17. In some embodiments, the dielectric layer 18 may be made of a low-k dielectric material. In some embodiments, the low-k dielectric material may include, for example, but not limited to, silicon oxide, silicon nitride, silicon oxynitride, silicon carbonitride, silicon oxycarbide, silicon oxycarbonitride, silicon carbide, an extreme low-k (ELK) dielectric material, or combinations thereof. Other suitable low-k dielectric materials are within the contemplated scope of the present disclosure. In some embodiments, the dielectric layer 18 may be deposited on the CESL 17 by a suitable deposition process as known to those skilled in the art of semiconductor fabrication, for example but not limited to, CVD, PECVD, ALD, or PEALD. Other suitable processes are within the contemplated scope of the present disclosure.

Referring to FIG. 1B and the example illustrated in FIG. 10, the method 100A then proceeds to step S11, where a planarization process is performed. The structure shown in FIG. 10 is subjected to the planarization process (for example but not limited to, chemical mechanical planarization (CMP)) so as to remove a portion of the dielectric layer 18, portions of the CESL 17, and portions of the first spacer layer 14 of the structure shown in FIG. 10 until the dummy gate structures 11′ are exposed.

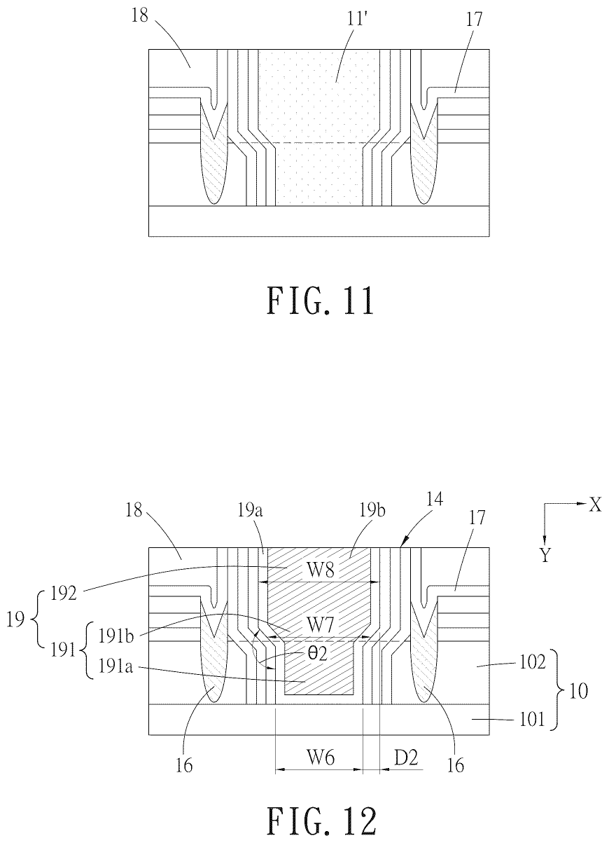

Referring to FIG. 1B and the example illustrated in FIG. 12, the method 100A then proceeds to step S12, where the dummy gate structures 11′ of the structure shown in FIG. 11 are replaced with metal gate structures 19 so as to form a plurality of transistors on the semiconductor substrate 10. The dummy gate structures 11′ of the structure shown in FIG. 11 are removed by one or more etching processes (for example, but not limited to, a wet etching process, a dry etching process, or a combination thereof) to form voids (not shown) defined by the first spacer layer 14. A high-k dielectric layer is conformally formed by a suitable deposition process as known to those skilled in the art of semiconductor fabrication (for example, but not limited to, CVD, PECVD, ALD, or PEALD) to cover the dielectric layer 18 and the first spacer layer 14. In some embodiments, the high-k dielectric layer may include, for example, but not limited to, HfO₂, HfSiO, HfSiON, HfTaO, HfTiO, HfZrO, or combinations thereof. Other suitable high-k dielectric materials are within the contemplated scope of the present disclosure. A metal-filling layer is then formed on the high-k dielectric layer to fill the voids by a suitable deposition process as known to those skilled in the art of semiconductor fabrication, for example, but not limited to, CVD, PECVD, ALD, PEALD, molecular layer deposition (MLD), physical vapor deposition (PVD), or sputtering. Other suitable processes are within the contemplated scope of the present disclosure. In some embodiments, the metal-filling layer may include, for example, but not limited to, aluminum, tungsten, copper, and combinations thereof. Other conductive metals are within the contemplated scope of the present disclosure. A planarization process (for example but not limited to, CMP) is performed to remove a portion of the metal-filling layer and a portion of the high-k dielectric layer until the dielectric layer 18 is exposed so as to form the metal gate structures 19. Each of the metal gate structures 19 includes a gate dielectric layer 19a conformally disposed on an inner wall of the first spacer layer 14 and on the substrate 10, and a metal gate 19b disposed on the gate dielectric layer 19a and separated from the first spacer layer 14 and the substrate 10 by the gate dielectric layer 19a. The gate dielectric layer 19a is made from the high-k dielectric layer, and the metal gate 19b is made from the metal-filling layer.

Each of the transistors thus formed includes one of the metal gate structures 19 and two corresponding ones of the source/drain structures 16 disposed at two opposite sides of the one of the metal gate structures 19. Each of the metal gate structures 19 includes an upper metal gate portion 192, and a lower metal gate portion 191 that is connected between the upper metal gate portion 192 and the main portion 102 of the semiconductor substrate 10 and that is disposed between two corresponding ones of the source/drain structures 16.

The lower metal gate portion 191 has a width in the horizontal direction (X), which is less than a width of the upper metal gate portion 192 in the horizontal direction (X). The lower metal gate portion 191 includes a lower part 191a and an upper part 191b connected between the lower part 191a and the upper metal gate portion 192. The lower part 191a of the lower metal gate portion 191 has a width (W6) in the horizontal direction (X). The upper metal gate portion 192 has a width (W8) in the horizontal direction (X), which is greater than the width (W6) of the lower part 191a of the lower metal gate portion 191. The upper part 191b of the lower metal gate portion 191 is tapered in the downward direction (Y) from the upper metal gate portion 192 to the lower part 191a of the lower metal gate portion 191. The upper part 191b of the lower metal gate portion 191 has a width (W7) in the horizontal direction (X), which ranges from about the width (W6) to about the width (W8). In some embodiments, the width (W8) ranges from about 25 nm to about 6000 nm. In some embodiments, a distance (D2) between a sidewall of the upper metal gate portion 192 and a corresponding sidewall of the lower part 191a of the lower metal gate portion 191 in the horizontal direction (X) ranges from about 5 nm to about 10 nm. A sidewall of the upper part 191b of the lower metal gate portion 191 and a corresponding sidewall of the lower part 191a of the lower metal gate portion 191 define an angle (Θ2), which is greater than about 90° and less than about 150°.

Referring to FIG. 1B and the example illustrated in FIG. 13, the method 100A proceeds to step S13, where a plurality of conductive contacts 20 are formed. The conductive contacts 20 are formed in the dielectric layer 18, and are connected to the source/drain structures 16, respectively. In some embodiments, the conductive contacts 20 are formed by the following processes.

A plurality of contact openings (not shown) are formed by patterning the dielectric layer 18 and the CESL 17 through a patterned mask layer (not shown) disposed on the structure shown in FIG. 12 using one or more suitable etching processes (for example, but not limited to, a dry etching process, a wet etching process, or a combination thereof). In some embodiments, after the contact openings are formed, the patterned mask layer may be removed by a suitable removal process (for example, but not limited to, an etching process or an ashing process). The contact openings are formed through the dielectric layer 18 and the CESL 17 to expose the source/drain structures 16 from the contact openings, respectively. A conductive material is then deposited to fill the contact openings, followed by removing excess of the conductive material by a planarization process, such as CMP. In some embodiments, the conductive material may include, for example, but not limited to, a metal or metal-containing material such as copper (Cu), tungsten (W), cobalt (Co), ruthenium (Ru), titanium (Ti), titanium nitride, tantalum (Ta), tantalum nitride, molybdenum (Mo), nickel (Ni), platinum (Pt), a low resistivity metal constituent, other suitable materials, alloys thereof, or combinations thereof. Other suitable conductive materials are within the contemplated scope of the present disclosure. In some embodiments, deposition of the conductive material may be performed by a suitable deposition technique, such as CVD, ALD, plating, or other suitable deposition techniques. The semiconductor device 200A is obtained accordingly. The semiconductor device 200A thus formed may include a plurality of the metal gate structures 19, each of which has a first width suitable for forming input-and-output field effect transistors (I/O FETs), and a plurality of the metal gate structures 19, each of which has a second width suitable for forming core field effect transistors (core FETs). The first width of each of the metal gate structures 19 for forming the I/O FETs is greater than the second width of each of the metal gate structures 19 for forming the core FETs. The I/O FETs can be used in high voltage devices. The core FETs can be used in logic devices.

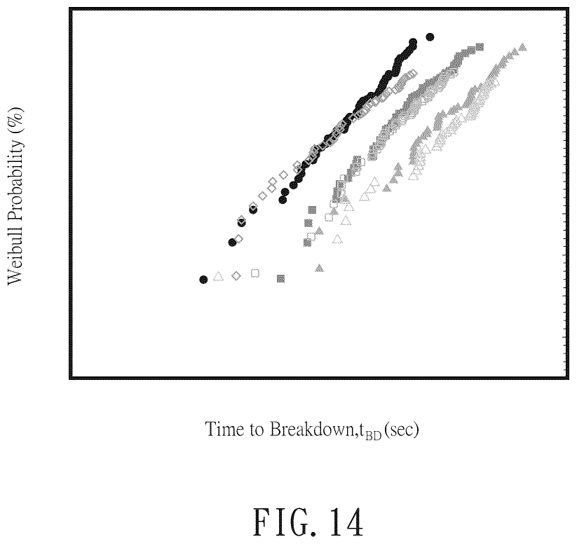

FIG. 14 shows the results of a Core SVT-PMOS TDDB (standard voltage threshold PMOS time dependent dielectric breakdown) test measured at a high voltage ranging from about 3.0 V to about 3.2 V of a semiconductor device including a metal gate structure with a specified profile in accordance with some embodiments. As shown in FIG. 14, it is evident that a semiconductor device including a metal gate structure with a specified profile of the present disclosure can successfully pass the high voltage reliability test without early failure.

In a method for manufacturing a semiconductor device of the present disclosure, dummy gate structures are trimmed by a trimming process which includes: (a) a first over-etching, (b) a second over-etching, (c) a third over-etching, (d) a first corner-trimming, and (e) a second corner-trimming. Each of the dummy gate structures formed by the trimming process has a specified profile in which a lower portion of each of the dummy gate structures has a width in a horizontal direction, which is less than a width of an upper portion of each of the dummy gate structures in the horizontal direction. Therefore, a process window for forming source/drain recesses adjacent to the dummy gate structures can be increased, and damage to the dummy gate structures which may be caused by an anisotropic etching process for forming the source/drain recesses can be prevented, such that an issue of formation of an open circuit (or bridging) between metal gate structures and source/drain regions to be formed can be eliminated.

In accordance with some embodiments of the present disclosure, a method for manufacturing a semiconductor device includes: forming a dummy gate structure on a semiconductor substrate, the dummy gate structure including a lower portion disposed on the semiconductor substrate and an upper portion disposed on the lower portion and opposite to the semiconductor substrate; and trimming the lower portion of the dummy gate structure by an etching process such that the lower portion of the dummy gate structure has a width less than that of the upper portion of the dummy gate structure.

In accordance with some embodiments of the present disclosure, the etching process includes a first over-etching and a second over-etching. The first over-etching is performed with a first pulsed bias voltage, a first bias power, and a first etching gas mixture including a first etching gas, a second etching gas, and a third etching gas. The second over-etching is performed after the first over-etching and with a second pulsed bias voltage, a second bias power, and a second etching gas mixture including a first etching gas, a second etching gas, and a third etching gas. The first etching gas of the second etching gas mixture has a concentration greater than that of the first etching gas of the first etching gas mixture.

In accordance with some embodiments of the present disclosure, the first etching gas of each of the first etching gas mixture and the second etching gas mixture is chlorine gas. The second etching gas of each of the first etching gas mixture and the second etching gas mixture is hydrogen bromide gas. The third etching gas of each of the first etching gas mixture and the second etching gas mixture is oxygen gas.

In accordance with some embodiments of the present disclosure, the etching process further includes a third over-etching performed after the second over-etching and with a first continuous bias voltage, a third bias power, and a third etching gas mixture including a first etching gas, a second etching gas, and a third etching gas. The first etching gas of the third etching gas mixture has a concentration less than that of the first etching gas of the second etching gas mixture.

In accordance with some embodiments of the present disclosure, the first etching gas of each of the first etching gas mixture, the second etching gas mixture, and the third etching gas mixture is chlorine gas. The second etching gas of each of the first etching gas mixture, the second etching gas mixture, and the third etching gas mixture is hydrogen bromide gas. The third etching gas of each of the first etching gas mixture, the second etching gas mixture, and the third etching gas mixture is oxygen gas.

In accordance with some embodiments of the present disclosure, the etching process further includes a first corner-trimming and a second corner-trimming. The first corner-trimming is performed after the third over-etching and with a second continuous bias voltage, a fourth bias power, and a fourth etching gas mixture including a first etching gas, a second etching gas, and a third etching gas. The second corner-trimming is performed after the first corner-trimming and with a third continuous bias voltage, a fifth bias power, and a fifth etching gas mixture including a first etching gas, a second etching gas, and a third etching gas. The first etching gas of the fifth etching gas mixture has a concentration greater than that of the first etching gas of the fourth etching gas mixture.

In accordance with some embodiments of the present disclosure, the first etching gas of each of the first etching gas mixture, the second etching gas mixture, the third etching gas mixture, the fourth etching gas mixture, and the fifth etching gas mixture is chlorine gas. The second etching gas of each of the first etching gas mixture, the second etching gas mixture, the third etching gas mixture, the fourth etching gas mixture, and the fifth etching gas mixture is hydrogen bromide gas. The third etching gas of each of the first etching gas mixture, the second etching gas mixture, the third etching gas mixture, the fourth etching gas mixture, and the fifth etching gas mixture is oxygen gas.

In accordance with some embodiments of the present disclosure, the fifth bias power for the second corner-trimming is greater than the first bias power for the first over-etching, the second bias power for the second over-etching, the third bias power for the third over-etching, and the fourth bias power for the first corner-trimming.

In accordance with some embodiments of the present disclosure, a method for manufacturing a semiconductor device includes: forming a dummy material layer on a semiconductor substrate including a main portion and a fin portion disposed on the main portion, such that the dummy material layer is disposed across the fin portion of the semiconductor substrate; patterning the dummy material layer to form a dummy gate structure that is disposed across the fin portion of the semiconductor substrate and that includes an upper portion and a lower portion connected between the upper portion of the dummy gate structure and the main portion of the semiconductor substrate, the lower portion of the dummy gate structure having a width in a horizontal direction parallel to an extension direction of the fin portion of the semiconductor substrate, the upper portion of the dummy gate structure having a width in the horizontal direction, and the width of lower portion of the dummy gate structure being greater than the width of the upper portion of the dummy gate structure; and trimming the lower portion of the dummy gate structure by an etching process such that the lower portion of the dummy gate structure, after being trimmed, has a width in the horizontal direction which is less than a width of the upper portion of the dummy gate structure in the horizontal direction.

In accordance with some embodiments of the present disclosure, the etching process includes a first dry etching and a second dry etching. The first dry etching is performed with a first pulsed bias voltage, a first bias power, and a first etching gas mixture including a first etching gas, a second etching gas, and a third etching gas. The second dry etching is performed after the first dry etching and with a second pulsed bias voltage, a second bias power, and a second etching gas mixture including a first etching gas, a second etching gas, and a third etching gas. The first etching gas of the second etching gas mixture has a concentration greater than that of the first etching gas of the first etching gas mixture.

In accordance with some embodiments of the present disclosure, the first etching gas of each of the first etching gas mixture and the second etching gas mixture is chlorine gas. The second etching gas of each of the first etching gas mixture and the second etching gas mixture is hydrogen bromide gas. The third etching gas of each of the first etching gas mixture and the second etching gas mixture is oxygen gas.

In accordance with some embodiments of the present disclosure, the etching process further includes a third dry etching performed after the second dry etching and with a first continuous bias voltage, a third bias power, and a third etching gas mixture including a first etching gas, a second etching gas, and a third etching gas. The first etching gas of the third etching gas mixture has a concentration less than that of the first etching gas of the second etching gas mixture.

In accordance with some embodiments of the present disclosure, the first etching gas of each of the first etching gas mixture, the second etching gas mixture, and the third etching gas mixture is chlorine gas. The second etching gas of each of the first etching gas mixture, the second etching gas mixture, and the third etching gas mixture is hydrogen bromide gas. The third etching gas of each of the first etching gas mixture, the second etching gas mixture, and the third etching gas mixture is oxygen gas.

In accordance with some embodiments of the present disclosure, the etching process further includes a fourth dry etching and a fifth dry etching. The fourth dry etching is performed after the third dry etching and with a second continuous bias voltage, a fourth bias power, and a fourth etching gas mixture including a first etching gas, a second etching gas, and a third etching gas. The fifth dry etching is performed after the fourth dry etching and with a third continuous bias voltage, a fifth bias power, and a fifth etching gas mixture including a first etching gas, a second etching gas, and a third etching gas. The first etching gas of the fifth etching gas mixture has a concentration greater than that of the first etching gas of the fourth etching gas mixture.

In accordance with some embodiments of the present disclosure, the first etching gas of each of the first etching gas mixture, the second etching gas mixture, the third etching gas mixture, the fourth etching gas mixture, and the fifth etching gas mixture is chlorine gas. The second etching gas of each of the first etching gas mixture, the second etching gas mixture, the third etching gas mixture, the fourth etching gas mixture, and the fifth etching gas mixture is hydrogen bromide gas. The third etching gas of each of the first etching gas mixture, the second etching gas mixture, the third etching gas mixture, the fourth etching gas mixture, and the fifth etching gas mixture is oxygen gas.

In accordance with some embodiments of the present disclosure, the fifth bias power for the fifth dry etching is greater than the first bias power for the first dry etching, the second bias power for the second dry etching, the third bias power for the third dry etching, and the fourth bias power for the fourth dry etching.

In accordance with some embodiments of the present disclosure, a semiconductor device includes a semiconductor substrate, a metal gate structure, and a pair of source/drain structures disposed at two opposite sides of the metal gate structure. The semiconductor substrate includes a main portion and a fin portion disposed on the main portion. The metal gate structure is disposed across the fin portion of the semiconductor substrate, and includes an upper metal gate portion and a lower metal gate portion connected between the upper metal gate portion and the main portion of the semiconductor substrate. The lower metal gate portion has a width in a horizontal direction parallel to an extension direction of the fin portion of the semiconductor substrate, the upper metal gate portion has a width in the horizontal direction, and the width of the lower metal gate portion is less than the width of the upper metal gate portion.

In accordance with some embodiments of the present disclosure, the lower metal gate portion includes a lower part and an upper part connected between the lower part and the upper metal gate portion. The upper part of the lower metal gate portion is tapered from the upper metal gate portion to the lower part of the lower metal gate portion in a downward direction transverse to the horizontal direction.

In accordance with some embodiments of the present disclosure, a distance between a sidewall of the upper metal gate portion and a corresponding sidewall of the lower part of the lower metal gate portion in the horizontal direction ranges from about 5 nm to about 10 nm.

In accordance with some embodiments of the present disclosure, a sidewall of the upper part of the lower metal gate portion and a corresponding sidewall of the lower part of the lower metal gate portion define an angle which is greater than about 900 and less than about 150°.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a dummy gate structure on a semiconductor substrate, the dummy gate structure including a lower portion disposed on the semiconductor substrate and an upper portion disposed on the lower portion and opposite to the semiconductor substrate; and
trimming the lower portion of the dummy gate structure by an etching process such that the lower portion of the dummy gate structure has a width less than that of the upper portion of the dummy gate structure.

2. The method as claimed in claim 1, wherein the etching process includes:
a first over-etching performed with a first pulsed bias voltage, a first bias power, and a first etching gas mixture including a first etching gas, a second etching gas, and a third etching gas; and
a second over-etching performed after the first over-etching and with a second pulsed bias voltage, a second bias power, and a second etching gas mixture including a first etching gas, a second etching gas, and a third etching gas, the first etching gas of the second etching gas mixture having a concentration greater than that of the first etching gas of the first etching gas mixture.

3. The method as claimed in claim 2, wherein:
the first etching gas of each of the first etching gas mixture and the second etching gas mixture is chlorine gas;
the second etching gas of each of the first etching gas mixture and the second etching gas mixture is hydrogen bromide gas; and
the third etching gas of each of the first etching gas mixture and the second etching gas mixture is oxygen gas.

4. The method as claimed in claim 2, wherein the etching process further includes:
a third over-etching performed after the second over-etching and with a first continuous bias voltage, a third bias power, and a third etching gas mixture including a first etching gas, a second etching gas, and a third etching gas, the first etching gas of the third etching gas mixture having a concentration less than that of the first etching gas of the second etching gas mixture.

5. The method as claimed in claim 4, wherein:
the first etching gas of each of the first etching gas mixture, the second etching gas mixture, and the third etching gas mixture is chlorine gas;
the second etching gas of each of the first etching gas mixture, the second etching gas mixture, and the third etching gas mixture is hydrogen bromide gas; and
the third etching gas of each of the first etching gas mixture, the second etching gas mixture, and the third etching gas mixture is oxygen gas.

6. The method as claimed in claim 4, wherein the etching process further includes:
a first corner-trimming performed after the third over-etching and with a second continuous bias voltage, a fourth bias power, and a fourth etching gas mixture including a first etching gas, a second etching gas, and a third etching gas; and
a second corner-trimming performed after the first corner-trimming and with a third continuous bias voltage, a fifth bias power, and a fifth etching gas mixture including a first etching gas, a second etching gas, and a third etching gas, the first etching gas of the fifth etching gas mixture having a concentration greater than that of the first etching gas of the fourth etching gas mixture.

7. The method as claimed in claim 6, wherein:
the first etching gas of each of the first etching gas mixture, the second etching gas mixture, the third etching gas mixture, the fourth etching gas mixture, and the fifth etching gas mixture is chlorine gas;
the second etching gas of each of the first etching gas mixture, the second etching gas mixture, the third etching gas mixture, the fourth etching gas mixture, and the fifth etching gas mixture is hydrogen bromide gas; and
the third etching gas of each of the first etching gas mixture, the second etching gas mixture, the third etching gas mixture, the fourth etching gas mixture, and the fifth etching gas mixture is oxygen gas.

8. The method as claimed in claim 6, wherein the fifth bias power for the second corner-trimming is greater than the first bias power for the first over-etching, the second bias power for the second over-etching, the third bias power for the third over-etching, and the fourth bias power for the first corner-trimming.

9. A method for manufacturing a semiconductor device, comprising:
forming a dummy material layer on a semiconductor substrate including a main portion and a fin portion disposed on the main portion, such that the dummy material layer is disposed across the fin portion of the semiconductor substrate;
patterning the dummy material layer to form a dummy gate structure that is disposed across the fin portion of the semiconductor substrate and that includes an upper portion and a lower portion connected between the upper portion of the dummy gate structure and the main portion of the semiconductor substrate, the lower portion of the dummy gate structure having a width in a horizontal direction parallel to an extension direction of the fin portion of the semiconductor substrate, the upper portion of the dummy gate structure having a width in the horizontal direction, and the width of lower portion of the dummy gate structure being greater than the width of the upper portion of the dummy gate structure; and
trimming the lower portion of the dummy gate structure by an etching process such that the lower portion of the dummy gate structure, after being trimmed, has a width in the horizontal direction which is less than a width of the upper portion of the dummy gate structure in the horizontal direction.

10. The method as claimed in claim 9, wherein the etching process includes:
a first dry etching performed with a first pulsed bias voltage, a first bias power, and a first etching gas mixture including a first etching gas, a second etching gas, and a third etching gas; and
a second dry etching performed after the first dry etching and with a second pulsed bias voltage, a second bias power, and a second etching gas mixture including a first etching gas, a second etching gas, and a third etching gas, the first etching gas of the second etching gas mixture having a concentration greater than that of the first etching gas of the first etching gas mixture.

11. The method as claimed in claim 10, wherein:
the first etching gas of each of the first etching gas mixture and the second etching gas mixture is chlorine gas;
the second etching gas of each of the first etching gas mixture and the second etching gas mixture is hydrogen bromide gas; and
the third etching gas of each of the first etching gas mixture and the second etching gas mixture is oxygen gas.

12. The method as claimed in claim 10, wherein the etching process further includes:
a third dry etching performed after the second dry etching and with a first continuous bias voltage, a third bias power, and a third etching gas mixture including a first etching gas, a second etching gas, and a third etching gas, the first etching gas of the third etching gas mixture having a concentration less than that of the first etching gas of the second etching gas mixture.

13. The method as claimed in claim 12, wherein:
the first etching gas of each of the first etching gas mixture, the second etching gas mixture, and the third etching gas mixture is chlorine gas;
the second etching gas of each of the first etching gas mixture, the second etching gas mixture, and the third etching gas mixture is hydrogen bromide gas; and
the third etching gas of each of the first etching gas mixture, the second etching gas mixture, and the third etching gas mixture is oxygen gas.

14. The method as claimed in claim 12, wherein the etching process further includes:
a fourth dry etching performed after the third dry etching and with a second continuous bias voltage, a fourth bias power, and a fourth etching gas mixture including a first etching gas, a second etching gas, and a third etching gas; and
a fifth dry etching performed after the fourth dry etching and with a third continuous bias voltage, a fifth bias power, and a fifth etching gas mixture including a first etching gas, a second etching gas, and a third etching gas, the first etching gas of the fifth etching gas mixture having a concentration greater than that of the first etching gas of the fourth etching gas mixture.

15. The method as claimed in claim 14, wherein:
the first etching gas of each of the first etching gas mixture, the second etching gas mixture, the third etching gas mixture, the fourth etching gas mixture, and the fifth etching gas mixture is chlorine gas;
the second etching gas of each of the first etching gas mixture, the second etching gas mixture, the third etching gas mixture, the fourth etching gas mixture, and the fifth etching gas mixture is hydrogen bromide gas; and
the third etching gas of each of the first etching gas mixture, the second etching gas mixture, the third etching gas mixture, the fourth etching gas mixture, and the fifth etching gas mixture is oxygen gas.

16. The method as claimed in claim 14, wherein the fifth bias power for the fifth dry etching is greater than the first bias power for the first dry etching, the second bias power for the second dry etching, the third bias power for the third dry etching, and the fourth bias power for the fourth dry etching.

17. A semiconductor device, comprising:
a semiconductor substrate including a main portion and a fin portion disposed on the main portion;
a metal gate structure disposed across the fin portion of the semiconductor substrate, and including an upper metal gate portion and a lower metal gate portion connected between the upper metal gate portion and the main portion of the semiconductor substrate, the lower metal gate portion having a width in a horizontal direction parallel to an extension direction of the fin portion of the semiconductor substrate, the upper metal gate portion having a width in the horizontal direction, and the width of the lower metal gate portion being less than the width of the upper metal gate portion; and
a pair of source/drain structures disposed at two opposite sides of the metal gate structure.

18. The semiconductor device as claimed in claim 17, wherein the lower metal gate portion includes a lower part and an upper part connected between the lower part and the upper metal gate portion, the upper part of the lower metal gate portion being tapered from the upper metal gate portion to the lower part of the lower metal gate portion in a downward direction transverse to the horizontal direction.

19. The semiconductor device as claimed in claim 18, wherein a distance between a sidewall of the upper metal gate portion and a corresponding sidewall of the lower part of the lower metal gate portion in the horizontal direction ranges from 5 nm to 10 nm.

20. The semiconductor device as claimed in claim 18, wherein a sidewall of the upper part of the lower metal gate portion and a corresponding sidewall of the lower part of the lower metal gate portion define an angle which is greater than 90° and less than 150°.
